(19) United States
(12) Patent Application Publication
(10) Pub. No.: US 2020/0020869 A1
(43) Pub. Date: Jan. 16, 2020

(54) FLEXIBLE DISPLAY DEVICE AND METHOD OF MANUFACTURING THE SAME

(71) Applicant: SAMSUNG DISPLAY CO., LTD., Yongin-si (KR)

(72) Inventors: Byunghoon KANG, Hwaseong-si (KR); Seung Jun MOON, Cheonan-si (KR); Dongkyun SEO, Seoul (KR); Hee Kyun SHIN, Incheon (KR); Junho SIM, Hwaseong-si (KR); Woo Jin CHO, Yongin-si (KR)

(21) Appl. No.: 16/404,058

(22) Filed: May 6, 2019

(30) Foreign Application Priority Data
Jul. 11, 2018 (KR) 10-2018-0080319

(51) Int. Cl. H01L 51/00; H01L 51/52; H01L 51/56

(52) U.S. Cl. CPC H01L 51/0097; H01L 51/5253; H01L 27/3244; H01L 2251/5323; H01L 51/56

(57) ABSTRACT

A method of manufacturing a flexible display device including preparing a support substrate, forming a first adhesive layer having a positive charge on the support substrate, the first adhesive layer including a polymer electrolyte and a graphene oxide, forming a second adhesive layer having a negative charge on the first adhesive layer, the second adhesive layer including a graphene oxide, forming a flexible substrate on the second adhesive layer, forming a display unit on the flexible substrate, and separating the support substrate and the flexible substrate.

### CROSS-REFERENCE TO RELATED APPLICATION

Korean Patent Application No. 10-2018-0080319, filed on Jul. 11, 2018 in the Korean Intellectual Property Office (KIPO), and entitled: “Flexible Display Device and Method of Manufacturing the Same,” is incorporated by reference herein in its entirety.

### BACKGROUND

### 1. Field

Embodiments relate to a display device. More particularly, embodiments relate to a flexible display device formed on a support substrate using an adhesive layer and a method of manufacturing the flexible display device.

### 2. Description of the Related Art

Liquid crystal displays, organic light emitting displays, and the like formed with a thin film transistor have gained increasing market share as displays for mobile devices, such as digital cameras, video cameras, cellular phones, or the like.

### SUMMARY

Embodiments are directed to a method of manufacturing a flexible display device including preparing a support substrate, forming a first adhesive layer having a positive charge on the support substrate, the first adhesive layer including a polymer electrolyte and a graphene oxide, forming a second adhesive layer having a negative charge on the first adhesive layer, the second adhesive layer including a graphene oxide, forming a flexible substrate on the second adhesive layer, forming a display unit on the flexible substrate, and separating the support substrate and the flexible substrate.

The support substrate is at least one of a glass substrate, a polymer film, and a silicon wafer.

Preparing the support substrate may include processing a surface of the support substrate to have a negative charge.

The polymer electrolyte may be at least one of poly(diallyldimethylammonium chloride) (PDDA), poly(ethylene imine) (PEI), poly(amic acid) (PAA), poly(styrene sulfonate) (PSS), poly(allyl amine) (PAA), chitosan (CS), poly(N-isopropyl acrylamide) (PNIPAM), poly(vinyl sulfate) (PVS), poly(allylamine) (PAH), and poly(methacrylic acid) (PMA).

Forming the first adhesive layer may include preparing a first adhesive solution having a positive charge, coating the first adhesive solution onto the support substrate; and drying the support substrate on which the first adhesive solution is coated.

Preparing the first adhesive solution may include mixing a polymer electrolyte solution and a graphene oxide solution.

The polymer electrolyte solution may have a positive charge. The graphene oxide solution may have a positive charge or a neutral charge.

Forming the second adhesive layer may include coating a second adhesive solution having a negative charge on the first adhesive layer and drying the first adhesive layer on which the second adhesive solution is coated.

Preparing the first adhesive solution may include mixing the second adhesive solution and a polymer electrolyte solution.

The method may further include, after forming the second adhesive layer and before forming the flexible substrate, forming a third adhesive layer having a positive charge on the second adhesive layer and forming a fourth adhesive layer having a negative charge on the third adhesive layer, the fourth adhesive layer including a graphene oxide.

The third adhesive layer may include a polymer electrolyte and a graphene oxide.

The third adhesive layer may include a graphene oxide.

Separating the support substrate and the flexible substrate may include separating the first adhesive layer and the second adhesive layer from each other.

Separating the support substrate and the flexible substrate may include separating the support substrate and the flexible substrate by using a peeling force.

The method may further include forming an encapsulation layer on the display unit.

Embodiments are also directed to a flexible display device including a flexible substrate, at least one adhesive layer having an electrical charge on a first surface of the flexible substrate, the at least one adhesive layer including a polymer electrolyte and a graphene oxide, a display unit on a second surface of the flexible substrate, and an encapsulation layer covering the display unit.

The flexible substrate may include at least one of polyester, polyvinyl, polycarbonate, polyethylene, polyacetate, polyimide, polyethersulfone (PES), polyacrylate (PAR), polyethylene naphthalate (PEN), and polyethylene terephthalate (PET).

The polymer electrolyte may be at least one of poly(diallyldimethylammonium chloride) (PDDA), poly(ethylene imine) (PEI), poly(amic acid) (PAA), poly(styrene sulfonate) (PSS), poly(allyl amine) (PAA), chitosan (CS), poly(N-isopropyl acrylamide) (PNIPAM), poly(vinyl sulfate) (PVS), poly(allylamine) (PAH), and poly(methacrylic acid) (PMA).

The at least one adhesive layer may include a first adhesive layer having a positive charge, the first adhesive layer including a polymer electrolyte and a graphene oxide, and a second adhesive layer having a negative charge, the second adhesive layer being between the first adhesive layer and the flexible substrate, and the second adhesive layer including a graphene oxide.

The display unit may include a pixel circuit layer on the flexible substrate, the pixel circuit layer including a thin film transistor, and an emission layer on the pixel circuit layer, the emission layer including an organic light emitting diode.

### BRIEF DESCRIPTION OF THE DRAWINGS

Features will become apparent to those of skill in the art by describing in detail exemplary embodiments with reference to the attached drawings in which:

FIG. 1 is a flowchart illustrating a method of manufacturing a flexible display device according to an embodiment.

FIGS. 2, 3, 4, 5, 6, 7, 8, and 9 illustrate cross-sectional views showing stages of a method of manufacturing a flexible display device according to an embodiment.

FIG. 10 illustrates a cross-sectional view of a flexible display device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

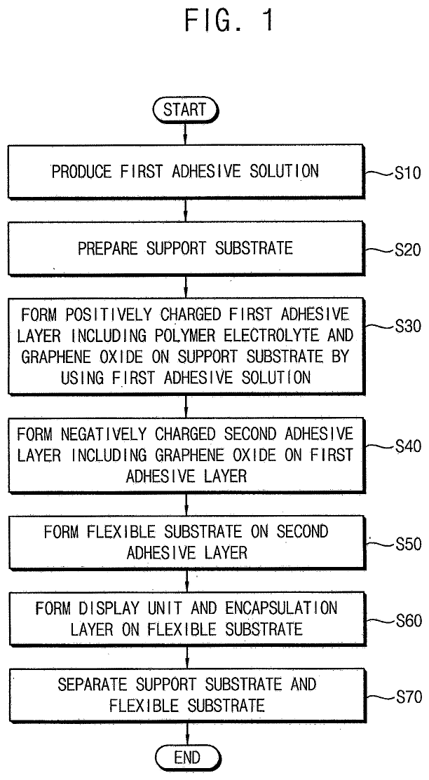

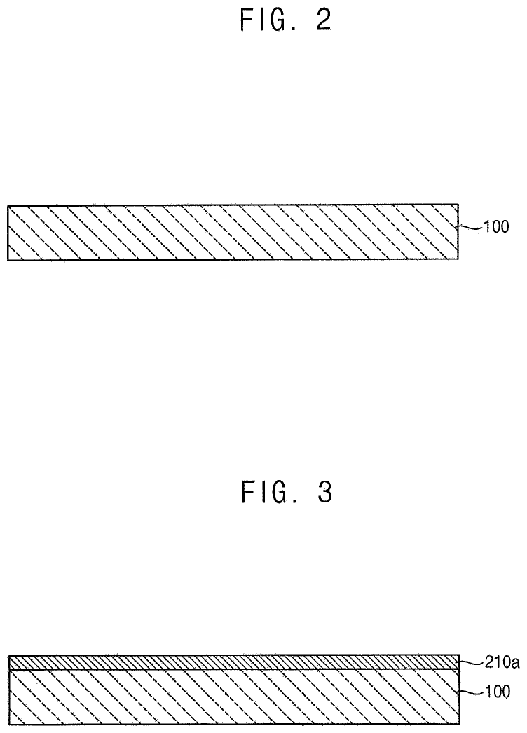

FIG. 1 is a flow chart illustrating a method of manufacturing a flexible display device according to an embodiment. FIGS. 2, 3, 4, 5, 6, 7, 8, and 9 illustrate cross-sectional views showing stages of a method of manufacturing a flexible display device according to an embodiment.

Referring to FIG. 1, a first adhesive solution may be produced (S10). The first adhesive solution may have a positive charge.

In an embodiment, a second adhesive solution having a negative charge may be produced, and then, the first adhesive solution may be produced using the second adhesive solution.

For example, a graphene oxide solution in a liquid phase may be produced using pre-graphene or mechanically ground graphene. The produced graphene oxide solution may have a reddish brown color or a yellowish brown color. The pre-graphene or mechanically ground graphene, and sodium nitrate (NaNO₃) may be added, for example, poured into, a sulfuric acid (H₂SO₄) solution, and potassium manganese oxide (KMnO₄) or potassium chlorate may be slowly poured and added therein while cooling the H₂SO₄ solution including the pre-graphene or mechanically ground graphene, and NaNO₃.

Additional sulfuric acid (H₂SO₄) may be slowly poured into the solution including the potassium manganese oxide (KMnO₄) or potassium chlorate, and hydrogen peroxide (H₂O₂) may be poured into the solution therein.

Centrifugation therefor may be performed, an upper solution may be poured away and discarded, and the remaining residue may be washed with H₂SO₄/H₂O₂ and finally washed with water. By repeating these procedures, a reddish brown and thick graphene oxide solution in, for example, a slightly gel state may be obtained. In the procedures, Mn³⁺, Mn⁴⁺, MnO₂, KMnO₄, HNO₃, HNO₄, CrO₃, or the like may be usable as a chemical oxidizer.

The graphene oxide solution produced in the method described above may be used as the second adhesive solution. The second adhesive solution may have a negative charge. To improve a characteristic of the negative charge, the second adhesive solution may further include metal nanowires or metal nanoparticles. For example, the second adhesive solution may include silver (Ag), copper (Cu), gold (Au), or the like. The metal nanowires or metal nanoparticles may be added in an amount of about 50 wt % or less to the second adhesive solution for transparency and coatability.

When the second adhesive solution has the negative charge, a process for forming or preparing the first adhesive solution having the positive charge may be performed. For example, the first adhesive solution may be formed by using the second adhesive solution.

A graphene oxide solution having a positive charge or a neutral charge may be formed by pouring an H₂SO₄ solution, an HNO₃ solution, or an HCl solution into the second adhesive solution having a negative charge. A functional group of the graphene oxide included in the second adhesive solution may be substituted, and a graphene oxide solution having a positive charge or a neutral charge may be formed. In some implementations, other suitable methods for forming the graphene oxide solution having a positive charge or a neutral charge may be used.

The graphene oxide solution having a positive charge or a neutral charge may be mixed with a polymer electrolyte solution. For example, the polymer electrolyte solution may include polymer such as poly(diallyldimethylammonium chloride) (PDDA), poly(ethylene imine) (PEI), poly(amic acid) (PAA), poly(styrene sulfonate) (PSS), poly(allyl amine) (PAA), chitosan (CS), poly(N-isopropyl acrylamide) (PNIPAM), poly(vinyl sulfate) (PVS), poly(allylamine) (PAH), poly(methacrylic acid) (PMA), or the like.

As described above, the graphene oxide solution having a positive charge or a neutral charge may be formed by using the second adhesive solution, which is a graphene oxide solution having a negative charge, and then mixing the graphene oxide solution having a positive charge or a neutral charge with the polymer electrolyte solution to produce the first adhesive solution having a positive charge. In some implementations, the second adhesive solution may be mixed with a polymer electrolyte solution to produce the first adhesive solution having a positive charge. In this case, a process for substituting the functional group of the graphene oxide included in the second adhesive solution may be omitted. Thus, the process of producing the first adhesive solution may be simplified.

In a general method of manufacturing a flexible display device, a graphene oxide solution having a positive charge is produced by substituting a functional group of a graphene oxide included in a graphene oxide solution having a negative charge, and then forming an adhesive layer having a positive charge on a support substrate by using the produced graphene oxide solution. In this case, since the graphene oxide itself has a negative charge, a solution stability of the graphene oxide solution having a positive charge may be relatively low. However, in the method of manufacturing the flexible display device according to the present embodiment, the first adhesive solution having a positive charge may be produced by mixing the graphene oxide solution with the polymer electrolyte solution having a positive charge, and then forming an adhesive layer having a positive charge on a support substrate by using the produced first adhesive solution. In this case, a solution stability of the first adhesive solution having a positive charge may be relatively high. A zeta potential of the first adhesive solution may be from about 40 mV to about 43 mV. In general, it may be evaluated that a solution stability is relatively excellent when a zeta potential of a solution is about 30 mV or more.

In an embodiment, a weight average molecular weight of a polymer material included in the polymer electrolyte solution may be in a range from about 600 to about 25,000, or, for example, from about 600 to about 3,000. If the molecular weight of the polymer material is more than 600, a coverage of a graphene oxide in a first adhesive layer 210a in FIG. 3 formed by coating the first adhesive solution may be sufficient. If the molecular weight of the polymer material is less than 25,000, the flexible display device damage due to an outgas emitted from the polymer material may be avoided.

The polymer electrolyte solution may have a positive charge. The first adhesive solution having a positive charge may be produced by mixing the polymer electrolyte solution with the graphene oxide solution having a positive charge or a neutral charge. In an embodiment, the produced undiluted first adhesive solution may be diluted before being used. For example, the undiluted first adhesive solution having hydrogen ion concentration of about pH 2.80 to about pH 3.50 may be diluted by about 120 times such that the first adhesive solution has a hydrogen ion concentration of about pH 4.42 to about pH 4.63.

Referring to FIGS. 1 and 2, a support substrate 100 may be prepared (S20).

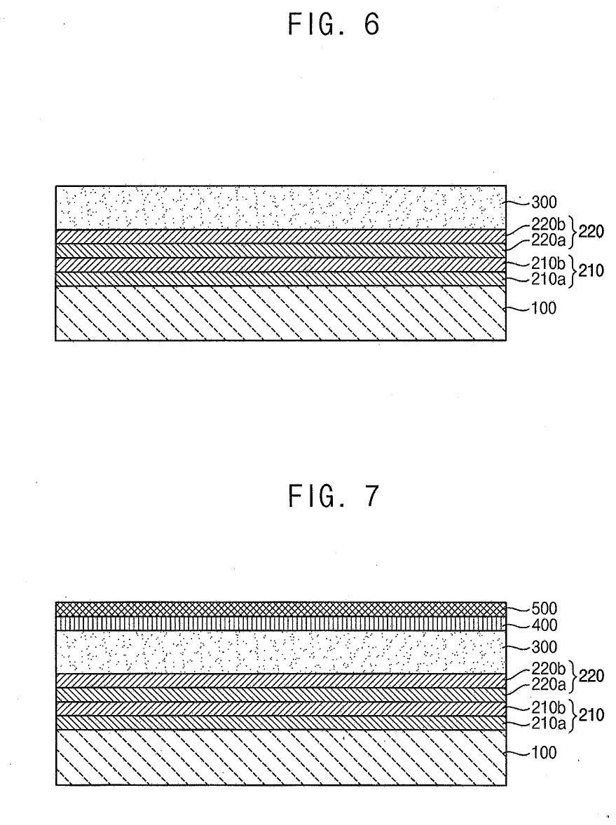

The support substrate 100 may be a substrate that supports a flexible substrate (300 in FIG. 6) to form the flexible display device. The support substrate 100 may be a suitable material having an electrical charge. The support substrate may be a glass substrate, a polymer film, and/or a silicon wafer.

A process of processing or treating a surface of the support substrate 100 to provide a negative charge may be additionally performed to facilitate forming the first adhesive layer 210a having a positive charge on the support substrate 100.

A surface of the support substrate 100 may provided with a negative charge by immersing the support substrate 100 into a polymer electrolyte solution having a negative charge. When the support substrate 100 having the negative charge is immersed into the first adhesive solution having the positive charge, the first adhesive layer 210a may be more easily formed on the surface of the support substrate 100. The polymer electrolyte solution having the negative charge may include, for example, sodium polystyrene sulfonate (NaPSS), polyvinyl sulfonic acid (PVS), or poly(1-[p-(3′-carboxy-4′-hydroxyphenyl)]azo (PCBS). As a method of processing the surface of the support substrate 100 to have the negative charge, besides dip coating in which the support substrate 100 is immersed into a polymer electrolyte having a negative charge, any one method selected from among spray coating, spin coating, screen coating, offset printing, inkjet printing, pad printing, knife coating, kiss coating, gravure coating, painting with a brush, ultrasound fine spray coating, and spray-mist coating may be used.

Referring to FIGS. 1 and 3, the first adhesive layer 210a may be formed on the support substrate 100 by using the first adhesive solution (S30). The first adhesive layer 210a may have a positive charge. The first adhesive layer 210a may include a polymer electrolyte and a graphene oxide. In an embodiment, the first adhesive layer 210a may consist of the polymer electrolyte and the graphene oxide.

The first adhesive solution having the positive charge may be coated onto the surface of the support substrate 100 by immersing the support substrate 100 in the first adhesive solution. As a suitable method of coating the first adhesive solution on the surface of the support substrate 100, any one method selected from among, for example, dip coating, spray coating, spin coating, screen coating, offset printing, inkjet printing, pad printing, knife coating, kiss coating, gravure coating, painting with a brush, ultrasound fine spray coating, and spray-mist coating may be used.

The first adhesive layer 210a having the positive charge may be formed on the support substrate 100 by drying the first adhesive solution coated on the surface of the support substrate 100. The drying process may be performed for about one hour at a temperature of about 80° C.

Before performing the drying process, rinsing the support substrate 100 on which the first adhesive solution is coated may be additionally performed using de-ionized (DI) water.

The first adhesive layer 210a may have a thickness from about 1 nm to about 30 nm. If the thickness of the first adhesive layer 210a more less than about 1 nm, it is easier to form the first adhesive layer 210a with a uniform thickness, so that it may be easier to provide a uniform adhesiveness throughout an entire surface of the first adhesive layer 210a. Further, if the thickness of the first adhesive layer 210a is less than about 30 nm, decrease in an adhesiveness of the first adhesive layer 210a may be avoided.

In a general method of manufacturing a flexible display device, an adhesive layer having a positive charge is formed on a support substrate by using a graphene oxide solution having a positive charge. In this case, a coverage of a graphene oxide in the adhesive layer having a positive charge may be relatively low (e.g., about 70%), such that a process of forming a plurality of adhesive layers on the support substrate may be required. However, in the method of manufacturing the flexible display device according to the present embodiment, the first adhesive layer 210a having a positive charge may be formed on the support substrate 100 by using the first adhesive solution having a positive charge and including the graphene oxide and the polymer electrolyte. In this case, a coverage of a graphene oxide in the first adhesive layer 210a having a positive charge may be relatively high (e.g., about 100%), therefore, a number of processes of forming adhesive layers on the support substrate 100 may be decreased.

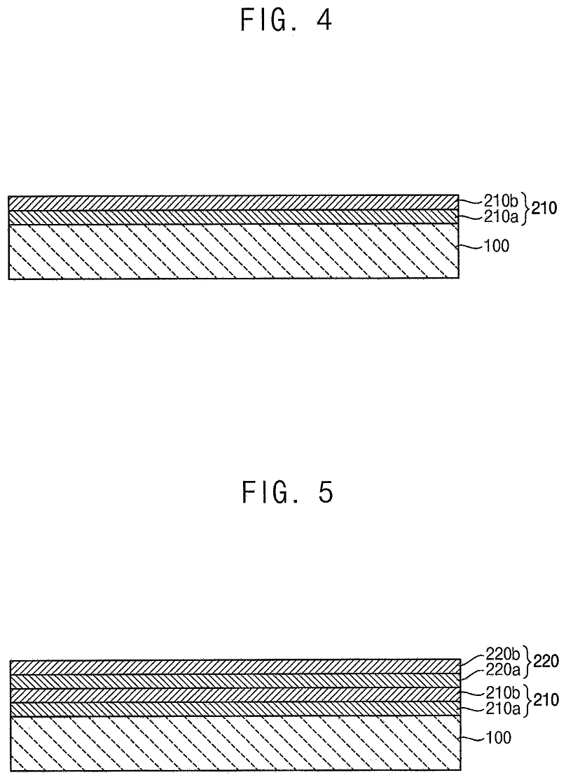

Referring to FIGS. 1 and 4, a second adhesive layer 210b may be formed on the first adhesive layer 210a (S40). The second adhesive layer 210b may have a negative charge, and may include a graphene oxide. In an embodiment, the second adhesive layer 210b may consist of the graphene oxide. Therefore, the first adhesive layer 210a and the second adhesive layer 210b having different electrical charges from each other may form a first adhesive pair 210 on the support substrate 100.

To form the second adhesive layer 210b on the first adhesive layer 210a, the second adhesive solution may be coated onto the first adhesive layer 210a. For example, the support substrate 100 on which the first adhesive layer 210a is formed may be immersed in the second adhesive solution having a negative charge. As a suitable method of coating the second adhesive solution onto the first adhesive layer 210a, any one method selected from among dip coating, spray coating, spin coating, screen coating, offset printing, inkjet printing, pad printing, knife coating, kiss coating, gravure coating, painting with a brush, ultrasound fine spray coating, and spray-mist coating may be used.

Next, the second adhesive layer 210b may be formed on the first adhesive layer 210a by performing a process of drying the second adhesive solution coated on the first adhesive layer 210a. The drying process may be performed for about one hour at a temperature of about 80° C.

Before performing the drying process, a process of rinsing the support substrate 100 on which the second adhesive solution is coated may be additionally performed using de-ionized water.

The second adhesive layer 210b may have a thickness from about lnm to about 30 nm.

It has been described above that the support substrate 100 is immersed into the polymer electrolyte solution having a negative charge to have a negative charge. In some implementations, the support substrate 100 may be immersed in the polymer electrolyte solution having a positive charge to have a positive charge. For example, the polymer electrolyte having the positive charge may include poly(diallyldimethylammonium chloride) (PDDA), poly(ethylene imine) (PEI), poly(amic acid) (PAA), poly(styrene sulfonate) (PSS), poly(allyl amine) (PAA), chitosan (CS), poly(N-isopropyl acrylamide) (PNIPAM), poly(vinyl sulfate) (PVS), poly(allylamine) (PAH), or poly(methacrylic acid) (PMA).

For example, after the support substrate 100 is immersed in the polymer electrolyte solution having the positive charge, the support substrate 100 having the positive charge may be then immersed in the second adhesive solution having a negative charge to easily form an adhesive layer on the support substrate 100. Thereafter, a drying process may be performed to form a second adhesive layer having a negative charge on the support substrate 100 having the positive charge.

Then, a first adhesive layer having a positive charge may be formed on the second adhesive layer having the negative charge for easy stacking. In order to form the first adhesive layer on the second adhesive layer, a drying process may be performed after the support substrate 100 has been immersed in the first adhesive solution. As described above, a first adhesive pair including the second adhesive layer and the first adhesive layer having different electrical charges from each other may be formed on the support substrate 100.

Referring to FIG. 5, a second adhesive pair 220 including a third adhesive layer 220a and a fourth adhesive layer 220b may be formed on the first adhesive pair 210.

The third adhesive layer 220a having a positive charge may be formed on the second adhesive layer 210b.

In an embodiment, the first adhesive solution may be coated onto the second adhesive layer 210b, and then, the second adhesive layer 210b coated with the first adhesive solution may be dried to form the third adhesive layer 220a. In this case, the third adhesive layer 220a may include the polymer electrolyte and the graphene oxide, like the first adhesive layer 210a.

In another embodiment, a graphene oxide solution may be coated onto the second adhesive layer 210b, and then the second adhesive layer 210b coated with the graphene oxide solution may be dried to form the third adhesive layer 220a. In this case, the third adhesive layer 220a may include only the graphene oxide unlike the first adhesive layer 210a. For example, the third adhesive layer 220a may not include the polymer electrolyte.

Next, the fourth adhesive layer 220b having a negative charge may be formed on the third adhesive layer 220a. The second adhesive solution may be coated on the third adhesive layer 220a, and then the third adhesive layer 220a coated with the second adhesive solution may be dried to form the fourth adhesive layer 220b. In this case, the fourth adhesive layer 220b may include the graphene oxide, like the second adhesive layer 210b.

It has been described above that four adhesive layers 210a, 210b, 220a, and 220b in which adjacent adhesive layers have different electrical charges may be alternately stacked on the support substrate 100. In some implementations, three or less, or five or more adhesive layers in which adjacent adhesive layers have different electrical charges may be alternately stacked on the support substrate 100.

Referring to FIGS. 1 and 6, a flexible substrate 300 may be formed on the fourth adhesive layer 220b (S50).

The flexible substrate 300 may be a flexible plastic substrate. The flexible substrate 300 may include polyester, polyvinyl, polycarbonate, polyethylene, polyacetate, polyimide, polyethersulfone (PES), polyacrylate (PAR), polyethylene naphthalate (PEN), and/or polyethylene terephthalate (PET).

A suitable method for forming the flexible substrate 300 on the second adhesive pair 220 may be used. For example, the flexible substrate 300 may be formed by coating a polymer material onto the second adhesive pair 220 and hardening the coated polymer material. The coating method may be any one selected from among spray coating, dip coating, spin coating, screen coating, offset printing, inkjet printing, pad printing, knife coating, kiss coating, gravure coating, painting with a brush, ultrasound fine spray coating, and spray-mist coating.

Referring to FIGS. 1 and 7, a display unit 400 and an encapsulation layer 500 may be formed on the flexible substrate 300 (S60).

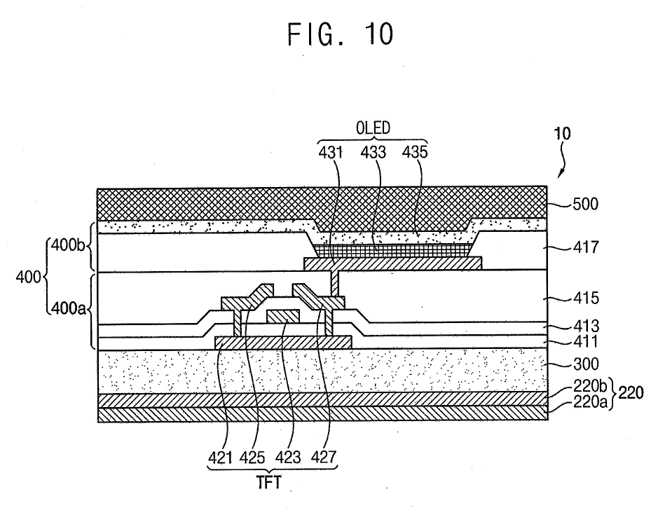

The display unit 400 may include a pixel circuit layer and an emission layer. The encapsulation layer 500 may be formed to cover the display unit 400 to prevent the deterioration of the display unit 400 due to external causes, such as external humidity, oxygen, or the like. The display unit 400 and the encapsulation layer 500 will be described below in more detail with reference to FIG. 10.

The display unit 400 and the encapsulation layer 500 may be formed after the formation of the flexible substrate 300, which is relatively flexible, on the support substrate 100, which is relatively rigid. Therefore, warpage or bending of the flexible substrate 300 during the formation of the display unit 400 and the encapsulation layer 500 may be reduced or prevented.

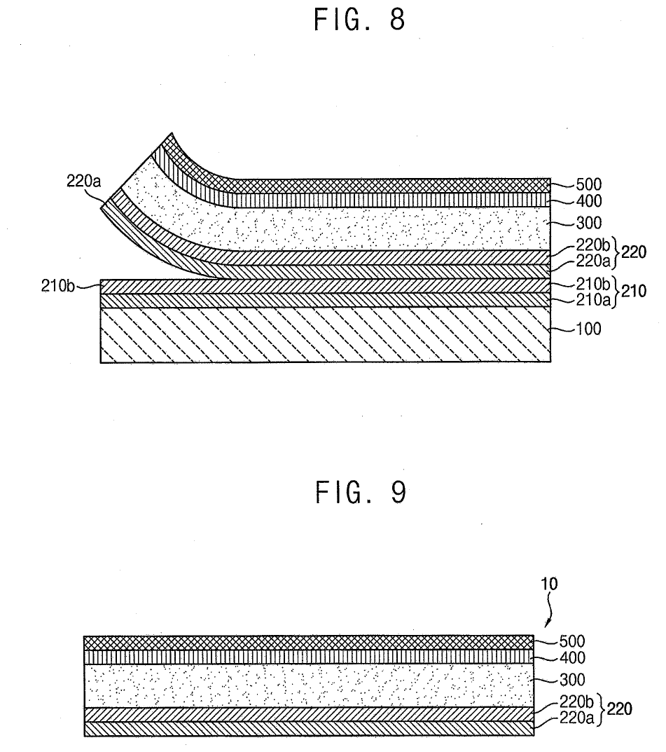

Referring to FIGS. 1 and 8, the flexible substrate 300 may be separated from the support substrate 100 (S70).

The adhesive layers 210a, 210b, 220a, and 220b in which adjacent adhesive layers have different electrical charges from each other may be formed between the support substrate 100 and the flexible substrate 300. Therefore, the Van der Waals force, which is a weak molecular force, may act between the adjacent adhesive layers having different electrical charges from each other. Further, when electrons of a π-π orbit function are widely spread on the surfaces of the adhesive layers 210a, 210b, 220a, and 220b, the adhesive layers 210a, 210b, 220a, and 220b may have a smooth surface.

Accordingly, the support substrate 100 and the flexible substrate 300 may be easily separated from each other by using a peeling force, e.g., using a tape on one or both of the support substrate 100 and the flexible substrate 300 to pull (peel) them apart. At least one adhesive layer may remain on each of a lower surface of the flexible substrate 300 and an upper surface of the support substrate 100 which are separated from each other. For example, the second adhesive pair 220 may remain on the lower surface of the flexible substrate 300, and the first adhesive pair 210 may remain on the upper surface of the support substrate 100 as illustrated in FIG. 8.

If an adhesiveness between the support substrate 100 and the flexible substrate 300 were to be relatively large, a stress necessary for separating the support substrate 100 and the flexible substrate 300 may be relatively large, and therefore, a thin film transistor or an organic light emitting diode in the display unit 400 may be damaged.

Table 1 below illustrates adhesiveness between a support substrate and a flexible substrate in Comparative examples 1 and 2 according to prior art and in an Embodiment Example 1 according to the present invention.

TABLE 1

| | Adhesive layers | Adhesiveness |
|---|---|---|
| Comparative | Two pairs of positive graphene oxide layer/ | Not measurable |
| example 1 | negative graphene oxide layer | |
| | Four pairs of positive graphene oxide layer/ | 6.98 gf/in |
| | negative graphene oxide layer | |
| Comparative | Two pairs of positive polymer electrolyte layer/ | 26.19 gf/in |
| example 2 | negative graphene oxide layer | |
| | Three pairs of positive polymer electrolyte layer/ | 4.34 gf/in |
| | negative graphene oxide layer | |
| | Four pairs of positive polymer electrolyte layer/ | 2.92 gf/in |
| | negative graphene oxide layer | |
| Embodiment | Two pairs of positive polymer electrolyte and | 9.74 gf/in |
| example 1 | graphene oxide mixed layer/negative graphene | |
| | oxide layer | |
| | Three pairs of positive polymer electrolyte and | 4.22 gf/in |
| | graphene oxide mixed layer/negative graphene | |
| | oxide layer | |
| | Four pairs of positive polymer electrolyte and | 2.83 gf/in |
| | graphene oxide mixed layer/negative graphene | |
| | oxide layer | |

As illustrated in Table 1 above, adhesiveness between adhesive layers in Embodiment Example 1 was shown to be less than adhesiveness between adhesive layers in Comparative Examples 1 and 2 according to Comparative Example 1 in which positive graphene oxide layer and negative graphene oxide layer are alternately stacked, Comparative Example 2 in which positive polymer electrolyte layer and negative graphene oxide layer are alternately stacked, and the Embodiment Example 1 in which positive polymer electrolyte and graphene oxide mixed layer, and negative graphene oxide layer are alternately stacked. Accordingly, the support substrate 100 and the flexible substrate 300 may be relatively easily separated according to the method of manufacturing the flexible display device according to the present embodiment.

FIG. 9 illustrates a flexible display device 10 separated from the support substrate 100 according to an embodiment.

Referring to FIG. 9, at least one adhesive layer having an electrical charge and including a polymer electrolyte and a graphene oxide may remain on the lower surface of the flexible substrate 300. For example, the second adhesive pair 220 including the third adhesive layer 220a and the fourth adhesive layer 220b may remain on the lower surface of the flexible substrate 300 as illustrated in FIG. 9. In some implementations, the second adhesive layer 210b or the first adhesive pair 210 including the first adhesive layer 210a and the second adhesive layer 210b may further remain below the flexible substrate 300.

Hereinafter, a flexible display device according to an embodiment will be described with reference to FIG. 10.

FIG. 10 illustrates a cross-sectional view of a flexible display device according to an embodiment.

Referring to FIG. 10, the display unit 400 may include a pixel circuit layer 400a and an emission layer 400b.

The pixel circuit layer 400a provided on the flexible substrate 300 may include a driving thin film transistor TFT for driving an organic light emitting diode OLED formed in the emission layer 400b, a switching thin film transistor, and the like.

When a top-gate driving thin film transistor TFT is provided in the pixel circuit layer 400a, a semiconductor layer 421, a gate insulation layer 411, a gate electrode 423, an insulation interlayer 413, a source electrode 425, and a drain electrode 427 may be sequentially formed on the flexible substrate 300.

The semiconductor layer 421 may be formed of a polysilicon. In this case, a set or predetermined area may be doped with impurities. In some implementations, the semiconductor layer 421 may be formed of an amorphous silicon instead of the polysilicon or formed of oxide semiconductor material, organic semiconductor material, or the like.

The driving thin film transistor TFT may include the semiconductor layer 421, the gate electrode 423, the source electrode 425, and the drain electrode 427.

A planarization layer (a protective layer and/or a passivation layer) 415 may be further provided on the source and drain electrodes 425 and 427 to protect and planarize the driving thin film transistor TFT.

The organic light emitting diode OLED disposed on the pixel circuit layer 400a and defined by a pixel defining layer 417 may include a pixel electrode 431, an organic emission layer 433 disposed on the pixel electrode 431, and an opposite electrode 435 formed on the organic emission layer 433.

The pixel electrode 431 may be an anode, and the opposite electrode 435 may be a cathode. In some implementations, according to a method of driving the flexible display device 10, the pixel electrode 431 may be a cathode, and the opposite electrode 435 may be an anode. When holes and electrons are respectively injected from the pixel electrode 431 and the opposite electrode 435 into the organic emission layer 433 and bonded (combined), light may be emitted.

The pixel electrode 431 may be electrically connected to the driving thin film transistor TFT formed in the pixel circuit layer 400a.

A structure in which the emission layer 400b is disposed on the pixel circuit layer 400a in which the driving thin film transistor TFT is disposed is illustrated in FIG. 10. In some implementations, various suitable changes in form are possible, such as a structure in which the pixel electrode 431 in the emission layer 400b is formed in the same layer as the semiconductor layer 421 of the driving thin film transistor TFT, a structure in which the pixel electrode 431 is formed in the same layer as the gate electrode 423, a structure in which the pixel electrode 431 is formed in the same layer as the source electrode 425 and the drain electrode 427, or the like.

The pixel electrode 431 included in the organic light emitting diode OLED may include a reflective electrode layer, and may include silver (Ag), magnesium (Mg), aluminum (Al), platinum (Pt), palladium (Pd), gold (Au), nickel (Ni), neodymium (Nd), iridium (Ir), chromium (Cr), or a compound thereof. Further, the pixel electrode 431 may include a transparent or translucent electrode layer.

The transparent or translucent electrode layer may include at least one selected from among indium tin oxide (ITO), indium zinc oxide (IZO), zinc oxide (ZnO), indium oxide (In₂O₃), indium gallium oxide (IGO) and aluminum zinc oxide (AZO).

The opposite electrode 435 disposed to face the pixel electrode 431 may be a transparent or translucent electrode, and may be formed of a metal thin film having a small (low) work function, including lithium (Li), calcium (Ca), lithium fluoride (LiF)/Ca, LiF/Al, Al, Ag, Mg, or a compound thereof. Further, an auxiliary electrode layer may be further formed of a material for forming a transparent electrode, such as an ITO, an IZO, an In₂O₃, or the like.

The organic emission layer 433 may be disposed between the pixel electrode 431 and the opposite electrode 435. The organic emission layer 433 may be formed of a low-molecular weight organic material or a high-molecular weight organic material.

Besides the organic emission layer 433, an intermediate layer having a hole transport layer (HTL), a hole injection layer (HIL), an electron transport layer (ETL), an electron injection layer (EIL), or the like may be selectively disposed.

Light emitted from the organic emission layer 433 may be directly emitted towards the opposite electrode 435 or may be reflected by the pixel electrode 431 including a reflective electrode and then emitted towards the opposite electrode 435 as a top emission display device.

In some implementations, light emitted from the organic emission layer 433 may be emitted towards the flexible substrate 300 as a bottom emission display device. In this case, the pixel electrode 431 may include a transparent or translucent electrode, and the opposite electrode 435 may include a reflective electrode.

Further, the flexible display device 10 may be a double-side emission display device to emit light in both directions, i.e., to the top and the bottom.

The encapsulation layer 500 formed to cover the display unit 400 may be formed by alternately stacking at least one organic layer and at least one inorganic layer.

The encapsulation layer 500 may function to prevent the infiltration or penetration of external humidity, oxygen, or the like into the organic light emitting diode OLED. Each of the at least one organic layer and the at least one inorganic layer may be plural in number.

The at least one organic layer may be formed of a polymer. For example, the at least one organic layer may be a single layer or a stacked layer formed of any one of polyethylene terephthalate (PET), polyimide, polycarbonate, epoxy, polyethylene, and polyacrylate (PAR). For example, the at least one organic layer may be formed of PAR including a monomer composite or mixture including a diacrylate-group monomer and a triacrylate-group monomer that has been high-molecularized, or, for example, polymerized. A monoacrylate-group monomer may be further included in the monomer composite or mixture. Further, a suitable photo initiator, such as thermoplastic polyolefin (TPO), may be further included in the monomer composite or mixture. The at least one inorganic layer may be a single layer or a stacked layer including a metal oxide or a metal nitride. For example, the at least one inorganic layer may include any one of a silicon nitride (SiNx), an aluminum oxide (Al₂O₃), a silicon oxide (SiO₂), and a titanium oxide (TiO₂).

The uppermost layer of the encapsulation layer 500 that is exposed to the outside may be formed as an inorganic layer to prevent the infiltration of humidity into the organic light emitting diode OLED.

The encapsulation layer 500 may include at least one sandwich structure in which at least one organic layer is inserted between at least two inorganic layers. In some implementations, the encapsulation layer 500 may include at least one sandwich structure in which at least one inorganic layer is inserted between at least two organic layers.

The encapsulation layer 500 may sequentially include a first inorganic layer, a first organic layer, and a second inorganic layer from an upper surface of the display unit 400. In some implementations, the encapsulation layer 500 may sequentially include a first inorganic layer, a first organic layer, a second inorganic layer, a second organic layer, and a third inorganic layer from the upper surface of the display unit 400. In some implementations, the encapsulation layer 500 may sequentially include a first inorganic layer, a first organic layer, a second inorganic layer, a second organic layer, a third inorganic layer, a third organic layer, and a fourth inorganic layer from upper surface of the display unit 400.

A halogenated metal layer including LiF may be further included between the display unit 400 and the first inorganic layer. The halogenated metal layer may prevent or reduce damage of the display unit 400 when the first inorganic layer is formed in a sputtering method or a plasma deposition method.

The first organic layer may be characterized by having a smaller area than the second inorganic layer. The second organic layer may also have a smaller area than the third inorganic layer. Further, the first organic layer may be characterized by being fully covered by the second inorganic layer, and the second organic layer may also be fully covered by the third inorganic layer.

The flexible display device according to the embodiments may be applied to a display device included in a computer, a notebook, a mobile phone, a smartphone, a smart pad, a PMP, a PDA, an MP3 player, or the like.

By way of summation and review, it is desirable that displays for mobile devices be thin, light, and flexible enough to be curved, so as to be easy to carry and be easily applied to various shapes of display devices. To this end, a method for performing a process of separating a support substrate and a flexible substrate from each other after mounting the flexible substrate on the support substrate has been introduced.

However, in a process of using a laser to separate the support substrate from the flexible substrate, as used in a comparable method, the separation may not be uniformly performed since energy is not uniformly emitted or distributed, or a flexible display device may be deteriorated due to the excessive emission of energy

Embodiments provide a method of manufacturing a flexible display device for easily separating a flexible substrate and a support substrate.

In the method of manufacturing the flexible display device according to the embodiments, the first adhesive layer having the positive charge and including the polymer electrolyte and the graphene oxide, and the second adhesive layer having the negative charge and including the graphene oxide may be alternately formed between the support substrate and the flexible substrate. Therefore, the support substrate and the flexible substrate may be easily separated.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A method of manufacturing a flexible display device, the method comprising:
preparing a support substrate;
forming a first adhesive layer having a positive charge on the support substrate, the first adhesive layer including a polymer electrolyte and a graphene oxide;
forming a second adhesive layer having a negative charge on the first adhesive layer, the second adhesive layer including a graphene oxide;
forming a flexible substrate on the second adhesive layer;
forming a display unit on the flexible substrate; and
separating the support substrate and the flexible substrate.

2. The method as claimed in claim 1, wherein the support substrate is at least one of a glass substrate, a polymer film, and a silicon wafer.

3. The method as claimed in claim 1, wherein preparing the support substrate includes processing a surface of the support substrate to have a negative charge.

4. The method as claimed in claim 1, wherein the polymer electrolyte is at least one of poly(diallyldimethylammonium chloride) (PDDA), poly(ethylene imine) (PEI), poly(amic acid) (PAA), poly(styrene sulfonate) (PSS), poly(allyl amine) (PAA), chitosan (CS), poly(N-isopropyl acrylamide) (PNIPAM), poly(vinyl sulfate) (PVS), poly(allylamine) (PAH), and poly(methacrylic acid) (PMA).

5. The method as claimed in claim 1, wherein forming the first adhesive layer includes:
preparing a first adhesive solution having a positive charge;
coating the first adhesive solution onto the support substrate; and
drying the support substrate on which the first adhesive solution is coated.

6. The method as claimed in claim 5, wherein preparing the first adhesive solution includes mixing a polymer electrolyte solution and a graphene oxide solution.

7. The method as claimed in claim 6, wherein:
the polymer electrolyte solution has a positive charge; and
the graphene oxide solution has a positive charge or a neutral charge.

8. The method as claimed in claim 5, wherein forming the second adhesive layer includes:
coating a second adhesive solution having a negative charge on the first adhesive layer; and
drying the first adhesive layer on which the second adhesive solution is coated.

9. The method as claimed in claim 8, wherein preparing the first adhesive solution includes mixing the second adhesive solution and a polymer electrolyte solution.

10. The method as claimed in claim 1, further comprising, after forming the second adhesive layer and before forming the flexible substrate:
forming a third adhesive layer having a positive charge on the second adhesive layer; and
forming a fourth adhesive layer having a negative charge on the third adhesive layer, the fourth adhesive layer including a graphene oxide.

11. The method as claimed in claim 10, wherein the third adhesive layer includes a polymer electrolyte and a graphene oxide.

12. The method as claimed in claim 10, wherein the third adhesive layer includes a graphene oxide.

13. The method as claimed in claim 1, wherein separating the support substrate and the flexible substrate includes separating the first adhesive layer and the second adhesive layer from each other.

14. The method as claimed in claim 1, wherein separating the support substrate and the flexible substrate includes separating the support substrate and the flexible substrate by using a peeling force.

15. The method as claimed in claim 1, further comprising forming an encapsulation layer on the display unit.

16. A flexible display device, comprising:
a flexible substrate;
at least one adhesive layer having an electrical charge on a first surface of the flexible substrate, the at least one adhesive layer including a polymer electrolyte and a graphene oxide;
a display unit on a second surface of the flexible substrate; and
an encapsulation layer covering the display unit.

17. The flexible display device as claimed in claim 16, wherein the flexible substrate includes at least one of polyester, polyvinyl, polycarbonate, polyethylene, polyacetate, polyimide, polyethersulfone (PES), polyacrylate (PAR), polyethylene naphthalate (PEN), and polyethylene terephthalate (PET).

18. The flexible display device as claimed in claim 16, wherein the polymer electrolyte is at least one of poly(diallyldimethylammonium chloride) (PDDA), poly(ethylene imine) (PEI), poly(amic acid) (PAA), poly(styrene sulfonate) (PSS), poly(allyl amine) (PAA), chitosan (CS), poly(N-isopropyl acrylamide) (PNIPAM), poly(vinyl sulfate) (PVS), poly(allylamine) (PAH), and poly(methacrylic acid) (PMA).

19. The flexible display device as claimed in claim 16, wherein the at least one adhesive layer includes:
a first adhesive layer having a positive charge, the first adhesive layer including a polymer electrolyte and a graphene oxide; and
a second adhesive layer having a negative charge, the second adhesive layer being between the first adhesive layer and the flexible substrate, and the second adhesive layer including a graphene oxide.

20. The flexible display device as claimed in claim 16, wherein the display unit includes:
a pixel circuit layer on the flexible substrate, the pixel circuit layer including a thin film transistor; and
an emission layer on the pixel circuit layer, the emission layer including an organic light emitting diode.
